(19) United States
(12) Patent Application Publication
(10) Pub. No.: US 2013/0183711 A1
(43) Pub. Date: Jul. 18, 2013

(54) LIQUID CRYSTALS WITH SWITCHABLE WETTABILITY FOR CELL SORTING

(71) Applicant: Angele Sjong, Louisville, CO (US)

(72) Inventor: Angele Sjong, Louisville, CO (US)

(73) Assignee: Empire Technology Development LLC

(21) Appl. No.: 13/816,694

(22) PCT Filed: Oct. 11, 2011
(86) PCT No.: PCT/US11/55751

§ 371 Date: Feb. 12, 2013

(51) Int. Cl. G01N 27/327; H05K 13/00

(52) U.S. Cl. CPC G01N 27/3275; H05K 13/0023
USPC 435/34; 435/287.1; 29/825

(57) ABSTRACT

Disclosed are methods and apparatuses for identifying and sorting cells based on the cells' response to an external stimulus. Cellular adherence to liquid crystals with tunable wettability is measured before and after an induced change in the liquid crystal wettability. The cell-based liquid crystal reorientation can be measured and used for monitoring and sorting of cells in a label-free manner, and thus provides a positive method for selecting cells, such as stem cells, for use in tissue engineering applications.

### TECHNICAL FIELD

The present disclosure relates generally to methods and devices for cell sorting. In particular, the present disclosure includes liquid crystal matrices for detecting cellular properties of biological cells subjected to a stimulus.

### BACKGROUND

The following description is provided to assist the understanding of the reader. None of the information provided or references cited is admitted to be prior art.

The separation of biological cells possessing different physical or chemical properties is often required in the medical and biotechnological fields. Cell sorting applications are particularly valuable for tissue engineering and diagnostics relating to disease pathology. Typically, cell sorting techniques are based on labeling or sensitizing a population of cells that may possess a specific marker, followed by detecting the presence or absence of the marker. Such sorting methods may include, inter alia, various flow cytometry applications, magnetic-based separation, magnetic-activated cell sorting (MACS), and fluorescence-activated cell sorting (FACS) methods.

Furthermore, the foregoing techniques require considerable time and the use of multiple, potentially toxic, reagents to distinguish between cell types and/or the stages of differentiation. In this regard, many tissue engineering applications require viable, pluripotent stem cells. In order for tissue engineering to be practical, however, high throughput applications are needed in order to support the rapid and accurate separation of native stem cells, and various other cell types, from undesired cell populations.

### SUMMARY

In one aspect, the present disclosure provides a method of cell sorting that includes depositing cells on a liquid crystal matrix; measuring liquid crystal matrix orientation; altering liquid crystal matrix wettability to induce a cellular response, wherein the cellular response produces a change in the liquid crystal matrix orientation; detecting the change in the liquid crystal matrix orientation; and sorting the cells based on the change in the liquid crystal matrix orientation. In illustrative embodiments, the liquid crystal matrix includes an apical film selected from the group consisting of extracellular matrix, basement membrane extract, and EHS matrix. In illustrative embodiments, the methods include adhering the cells to the apical film after depositing the cells on the liquid crystal matrix with the apical film.

In illustrative embodiments, the methods include removing the cells from the liquid crystal matrix, wherein the removing occurs after sorting the cells based on the change in the liquid matrix orientation. In illustrative embodiments, removing the cells from the liquid crystal matrix is by fluid flow or laser dissection. In other embodiments, the cells are collected after removing the cells from the liquid crystal matrix. In illustrative embodiments, the liquid crystal matrix orientation is by optoelectronic measuring. In illustrative embodiments, the optoelectronic measuring is by polarized light microscopy.

In illustrative embodiments, detecting the change in the liquid crystal matrix orientation is by optoelectronic detecting. In illustrative embodiments, detecting the change by optoelectronic detecting is by polarized light microscopy. In other embodiments, depositing the cells on the liquid crystal matrix is by liquid nozzle spray or polydimethylsiloxane stamp. In illustrative embodiments, the liquid crystal matrix is selected from the group consisting of: 4-(3-acryloyloxypropyloxy)-benzoic acid 2-methyl-1,4-phenylene ester; 4-trans-propylcyclohexylcyanobenzene; 4-trans-butylcyclohexylcyanobenzene; 4-trans-pentylcyclohexylcyanobenzene; 4-trans-heptylcyclohexylcyanobenzene; 4-cyano-4′-trans-pentylcyclohexanebiphenyl; 4-trans-propylcyclohexyl-4′-ethylbiphenyl; 4-trans-propylcyclohexyl-4′-propylbiphenyl; 4-ethyl-4′-cyanobiphenyl; 4-propyl-4′-cyanobiphenyl; 4-butyl-4′-cyanobiphenyl; 4-pentyl-4′-cyanobiphenyl; and 4-heptyl-4′-cyanobiphenyl.

In illustrative embodiments, ferroelectric nanoparticles are applied to the liquid crystal matrix prior to altering the liquid crystal matrix wettability. In illustrative embodiments, the ferroelectric nanoparticles are selected from the group consisting of Sn₂P₂S₆, BaTiO₃, PbTiO₃, and lead zirconate titanate (PZT). In other embodiments, the liquid crystal matrix wettability is altered by applying a low voltage electric field of about 0.01 V/μm to about 0.1 V/μm. In illustrative embodiments, the cells are selected from the group consisting of stem cells, mammalian cells, bacterial cells, insect cells, human cells, skin cells, muscle cells, epithelial cells, endothelial cells, umbilical vessel cells, corneal cells, cardiomyocytes, aortic cells, corneal epithelial cells, aortic endothelial cells, fibroblasts, hair cells, keratinocytes, melanocytes, adipose cells, bone cells, osteoblasts, airway cells, microvascular cells, mammary cells, vascular cells, chondrocytes, and placental cells, or any combination thereof. In illustrative embodiments, the cells are stem cells. In illustrative embodiments, the cellular response is based the cells stage of cellular differentiation. In some embodiments, the methods do not include the use of antibodies.

In one aspect, the present disclosure provides a cell sorting apparatus composed of a rotatable carousel with one or more platforms, wherein the one or more platforms include a liquid crystal matrix configured to receive cells; an electric source capable of providing a low voltage electric field to the one or more platforms with the liquid crystal matrix; and an optoelectronic device configured to detect one or more liquid crystal matrix orientations. In illustrative embodiments, the apparatus includes a cell dispenser. In illustrative embodiments, the cell dispenser has a spray nozzle or a polydimethylsiloxane stamp. In illustrative embodiments, the apparatus further includes one or more cell collection vessels.

In illustrative embodiments, the liquid crystal matrix is selected from the group consisting of: 4-(3-acryloyloxypropyloxy)-benzoic acid 2-methyl-1,4-phenylene ester; 4-trans-propylcyclohexylcyanobenzene; 4-trans-butylcyclohexylcyanobenzene; 4-trans-pentylcyclohexylcyanobenzene; 4-trans-heptylcyclohexylcyanobenzene; 4-cyano-4′-trans-pentylcyclohexanebiphenyl; 4-trans-propylcyclohexyl-4′-ethylbiphenyl; 4-trans-propylcyclohexyl-4′-propylbiphenyl; 4-ethyl-4′-cyanobiphenyl; 4-propyl-4′-cyanobiphenyl; 4-butyl-4′-cyanobiphenyl; 4-pentyl-4′-cyanobiphenyl; and 4-heptyl-4′-cyanobiphenyl. In illustrative embodiments, the liquid crystal matrix has an apical film selected from the group consisting of extracellular matrix, basement membrane extract, and EHS matrix.

In illustrative embodiments, the low voltage is selected to induce a change in wettability of the liquid crystal matrix. In illustrative embodiments, the apparatus has a laser or fluid flow chamber, or both. In illustrative embodiments, the optoelectronic device is a polarizable light microscope. In other embodiments, the liquid crystal matrix further comprises ferroelectric nanoparticles selected from the group consisting of Sn₂P₂S₆, BaTiO₃, PbTiO₃, lead zirconate titanate (PZT), and combinations thereof. In illustrative embodiments, the low voltage electric field is about 0.01 V/μm to about 0.1 V/μm. In illustrative embodiments, the cells are selected from the group consisting of stem cells, mammalian cells, bacterial cells, insect cells, human cells, skin cells, muscle cells, epithelial cells, endothelial cells, umbilical vessel cells, corneal cells, cardiomyocytes, aortic cells, corneal epithelial cells, aortic endothelial cells, fibroblasts, hair cells, keratinocytes, melanocytes, adipose cells, bone cells, osteoblasts, airway cells, microvascular cells, mammary cells, vascular cells, chondrocytes, and placental cells, or any combination thereof. In illustrative embodiments, the cells are stem cells.

In one aspect, the present disclosure provides a cell sorting method that includes depositing cells on one or more platforms containing a liquid crystal matrix, wherein the one or more platforms are affixed to a rotatable carousel; rotating the carousel to align the one or more platforms with an electric field source; applying an electric current to the one or more platforms aligned with the electric field source, wherein the electric current induces a change in wettability of the liquid crystal matrix; measuring the cells' response to the change in wettability, wherein the response depends on a cellular differentiation stage, and wherein the differentiation stage induces a measurable change in the matrix orientation; and sorting the cells based on the response. In illustrative embodiments, rotating the carousel provides for separate, sequential or simultaneous alignment of the one or more platforms with the electric field source.

In illustrative embodiments, the methods further include removing the cells from the liquid crystal matrix, wherein the removing occurs after sorting the cells based on the response. In illustrative embodiments, removing the cells from the liquid crystal matrix is by fluid flow or laser dissection. In illustrative embodiments, the methods include collecting the cells after sorting the cells based on the response. In illustrative embodiments, the liquid crystal matrix includes an apical film selected from the group consisting of matrigel or extracellular matrix.

In illustrative embodiments, the methods include adhering the cells to the apical film after depositing the cells on the liquid crystal matrix. In illustrative embodiments, measuring the cells' response to the change in wettability is by optoelectronic measuring. In illustrative embodiments, the optoelectronic measuring is by polarized light microscopy. In illustrative embodiments, depositing the cells on the one or more platforms is by liquid nozzle spray or polydimethylsiloxane stamp. In other embodiments, the liquid crystal matrix is selected from the group consisting of: 4-(3-acryloyloxypropyloxy)-benzoic acid 2-methyl-1,4-phenylene ester; 4-trans-propylcyclohexylcyanobenzene; 4-trans-butylcyclohexylcyanobenzene; 4-trans-pentylcyclohexylcyanobenzene; 4-trans-heptylcyclohexylcyanobenzene; 4-cyano-4′-trans-pentylcyclohexanebiphenyl; 4-trans-propylcyclohexyl-4′-ethylbiphenyl; 4-trans-propylcyclohexyl-4′-propylbiphenyl; 4-ethyl-4′-cyanobiphenyl; 4-propyl-4′-cyanobiphenyl; 4-butyl-4′-cyanobiphenyl; 4-pentyl-4′-cyanobiphenyl; and 4-heptyl-4′-cyanobiphenyl.

In illustrative embodiments, the methods include applying ferroelectric nanoparticles to the liquid crystal matrix prior to applying the electric current. In other embodiments, the ferroelectric nanoparticles are selected from the group consisting of Sn₂P₂S₆, BaTiO₃, PbTiO₃, lead zirconate titanate (PZT), and combinations thereof. In illustrative embodiments, the cells are selected from the group consisting of stem cells, mammalian cells, bacterial cells, insect cells, human cells, skin cells, muscle cells, epithelial cells, endothelial cells, umbilical vessel cells, corneal cells, cardiomyocytes, aortic cells, corneal epithelial cells, aortic endothelial cells, fibroblasts, hair cells, keratinocytes, melanocytes, adipose cells, bone cells, osteoblasts, airway cells, microvascular cells, mammary cells, vascular cells, chondrocytes, and placental cells, or any combination thereof. In illustrative embodiments, the cells are stem cells. In illustrative embodiments, the methods do not require the use of antibodies.

In one aspect, the present disclosure provides a method of manufacturing a cell sorting apparatus, which includes applying a liquid crystal matrix to one or more platforms, wherein the liquid crystal matrix is configured to receive cells; introducing the one or more platforms to a rotatable carousel having one or more apertures such that the one or more apertures receive the one or more platforms; electrically connecting a low voltage electric field source to the one or more platforms; and arranging an optoelectronic device with respect to the one or more platforms, wherein the optoelectronic device is configured to measure liquid crystal matrix orientation.

In illustrative embodiments, the liquid crystal matrix has an apical film selected from the group consisting of extracellular matrix, basement membrane extract, and EHS matrix. In other embodiments, the method includes arranging one or more vessels for collecting the cells. In illustrative embodiments, the liquid crystal matrix is selected from the group consisting of: 4-(3-acryloyloxypropyloxy)-benzoic acid 2-methyl-1,4-phenylene ester; 4-trans-propylcyclohexylcyanobenzene; 4-trans-butylcyclohexylcyanobenzene; 4-trans-pentylcyclohexylcyanobenzene; 4-trans-heptylcyclohexylcyanobenzene; 4-cyano-4′-trans-pentylcyclohexanebiphenyl; 4-trans-propylcyclohexyl-4′-ethylbiphenyl; 4-trans-propylcyclohexyl-4′-propylbiphenyl; 4-ethyl-4′-cyanobiphenyl; 4-propyl-4′-cyanobiphenyl; 4-butyl-4′-cyanobiphenyl; 4-pentyl-4′-cyanobiphenyl; and 4-heptyl-4′-cyanobiphenyl. In illustrative embodiments, the methods includes connecting a laser source or fluid flow chamber to the rotatable carousel.

The foregoing summary is illustrative only and is not intended to be in any way limiting. In addition to the illustrative aspects, embodiments, and features described above, further aspects, embodiments, and features will become apparent by reference to the following drawings and the detailed description.

### BRIEF DESCRIPTION OF THE FIGURES

FIG. 1 is a diagrammatic representation of the liquid crystal based cell sorting methods disclosed herein.

FIG. 2 is an illustrative embodiment of a liquid crystal cell sorting apparatus.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

The definitions of certain terms as used in this specification are provided below. Unless defined otherwise, all technical and scientific terms used herein generally have the same meaning as commonly understood by one of ordinary skill in the art to which this invention belongs.

As used herein, unless otherwise stated, the singular forms “a,” “an,” and “the” include plural reference. Thus, for example, a reference to “a cell” or “the cell” includes a plurality of cells.

As used herein, the term “about” will be understood by persons of ordinary skill in the art and will vary to some extent depending upon the context in which it is used. If there are uses of the term which are not clear to persons of ordinary skill in the art, given the context in which it is used, the term “about” in reference to quantitative values will mean up to plus or minus 10% of the enumerated value.

As used herein, the term “aggregation” or “cell aggregation” refers to a process whereby biomolecules, such as polypeptides, or cells stably associate with each other to form a multimeric, insoluble complex, which does not disassociate under physiological conditions unless a disaggregation step is performed.

As used herein the term “antibody” refers to an immunoglobulin and any antigen-binding portion of an immunoglobulin, e.g., IgG, IgD, IgA, IgM and IgE, or a polypeptide that contains an antigen binding site, which specifically binds or “immunoreacts with” an antigen. Antibodies can comprise at least one heavy (H) chain and at least one light (L) chain inter-connected by at least one disulfide bond. The term “V_{H}” refers to a heavy chain variable region of an antibody. The term “V_{L}” refers to a light chain variable region of an antibody. In some embodiments, the term “antibody” specifically covers monoclonal and polyclonal antibodies. A “polyclonal antibody” refers to an antibody which has been derived from the sera of animals immunized with an antigen or antigens. A “monoclonal antibody” refers to an antibody produced by a single clone of hybridoma cells.

As used herein, the term “antigen” refers to any molecule to which an antibody can specifically bind. Antigens typically provoke an immune response in an individual, and this immune response may involve either antibody production or the activation of specific immunologically competent cells, or both. The skilled artisan will understand that any macromolecule, including virtually all proteins, peptides, and cell-surface molecules can serve as an antigen under suitable conditions. Cell surface antigens are molecules expressed on the surface of a cell, which are recognized by an antibody.

As used herein, the terms “cell type” or “stage of cell differentiation” are used interchangeably in the context of distinguishing or discriminating between different cell groups. The present disclosure provides a mechanism for sorting cells based on the cells' response to an external stimuli. As such, when cells possess distinct characteristics imparting a differential response to an external stimuli, the cells can be said to be distinguished or separated from different cells that do have the same response. This response is measured through liquid crystal matrix orientation, and, thus, various cell types, e.g., mammalian, yeast, bacterial, insect, and/or tissue specific cells, and the like, or cells of one type but at a specific stage of differentiation, e.g., totipotent, pluripotent, multipotent, etc., will differentially respond to the external stimuli, thereby effectively separating or sorting based on their response.

As used herein, the term “culture vessel” or “vessel” or “vesicle” refers to a glass, plastic, or metal container that can provide an aseptic or natural environment for collecting distinct populations of cells.

As used herein, the phrase “difference of the level” refers to differences in the quantity of a particular marker, such as a cell surface antigen, biomarker protein, nucleic acid, or a difference in the response of a particular cell type to a stimulus, e.g., a change in surface adhesion, in a sample as compared to a control or reference level. In illustrative embodiments, a “difference of a level” is a difference between the level of a marker present in a sample as compared to a control of at least about 1%, at least about 2%, at least about 3%, at least about 5%, at least about 10%, at least about 15%, at least about 20%, at least about 25%, at least about 30%, at least about 35%, at least about 40%, at least about 50%, at least about 60%, at least about 75%, at least about 80% or more.

As used herein, the terms “expression” or “gene expression” refer to the process of converting genetic information encoded in a gene into RNA, e.g., mRNA, rRNA, tRNA, or snRNA, through transcription of the gene, i.e., via the enzymatic action of an RNA polymerase, and for protein encoding genes, into protein through translation of mRNA. Gene expression can be regulated at many stages in the process. “Up-regulation” or “activation” refers to regulation that increases the production of gene expression products, i.e., RNA or protein, while “down-regulation” or “repression” or “knock-down” refers to regulation that decreases production. Molecules, e.g., transcription factors that are involved in up-regulation or down-regulation are often called “activators” and “repressors,” respectively.

As used herein, the terms “extracellular matrix,” “ECM,” or “apical film” are used interchangeably, and encompass various liquid, gelatinous, semi-solid, or solid protein mixtures congruent with the complex extracellular environment found in many tissues. The extracellular matrix may be employed as a substrate for cell and tissue culture preparations or as a surface for cell adhesion to a liquid crystal matrix. The “extracellular matrix” may also include basement membrane extract and/or Engelbreth-Holm-Swarm (EHS) matrix.

As used herein, the term “fluorescent label” refers to small molecules, including, e.g., antibodies or proteins, which fluoresce at a characteristic wavelength of emission when exposed to electromagnetic radiation of an appropriate wavelength of excitation.

As used herein, an “imaging agent” refers to any substance used for visually reporting a cell type, the stage of cellular differentiation, a cell's state, or the state of subcellular structures or organelles without otherwise generally affecting the cell.

As used herein, the term “laser” refers to electromagnetic radiation of any frequency that is amplified by stimulated emission of radiation. A laser also refers to a device that emits electromagnetic radiation through a process called stimulated emission. Laser light is usually spatially coherent, which means that the light either is emitted in a narrow, low-divergence beam, or can be converted into one with the help of optical components such as lenses.

As used herein, the terms “liquid crystal,” “LC,” “liquid crystal matrix” or “LC matrix” are used interchangeably. These terms refer to organic materials that are neither liquid nor crystalline. When liquid crystals are placed in an electric field the liquid crystal molecules align parallel to the electric field lines. “Nematic liquid crystals” refers to thread-like compounds that are free to move with respect to other nematic liquid crystals, i.e., they are not sterically constrained. The molecular alignment of nematic liquid crystals can be adjusted by, e.g., applying electric fields or a measureable force such as an increase or decrease in cellular adhesion thereto. The alignment of nematic liquid crystals is related to its characteristic optical properties, which is detected via light transmission microscopy. Non-limiting examples of liquid crystal matrices include, e.g., 4-(3-acryloyloxypropyloxy)-benzoic acid 2-methyl-1,4-phenylene ester; 4-trans-propylcyclohexylcyanobenzene; 4-trans-butylcyclohexylcyanobenzene; 4-trans-pentylcyclohexylcyanobenzene; 4-trans-heptylcyclohexylcyanobenzene; 4-cyano-4′-trans-pentylcyclohexanebiphenyl; 4-trans-propylcyclohexyl-4′-ethylbiphenyl; 4-trans-propylcyclohexyl-4′-propylbiphenyl; 4-ethyl-4′-cyanobiphenyl; 4-propyl-4′-cyanobiphenyl; 4-butyl-4′-cyanobiphenyl; 4-pentyl-4′-cyanobiphenyl; and 4-heptyl-4′-cyanobiphenyl.

As used herein, the term “sample” may include, but is not limited to, bodily tissue or a bodily fluid such as blood (or a fraction of blood such as plasma or serum), lymph, mucus, tears, saliva, sputum, urine, semen, stool, CSF, ascities fluid, or whole blood, and including biopsy samples of body tissue. A sample may also include an in vitro culture of cells. A sample may be obtained from any subject or the environment. In this respect, an environmental sample may include a solid, liquid or gaseous sample, which is obtained from a desired area or location to be evaluated.

As used herein, the term “stem cell” generally refers to any cells that have the ability to divide for indefinite periods of time and to give rise to specialized cells. The term “stem cell” includes but is not limited, to the following: (a) totipotent cells such as an embryonic stem cell, an extra-embryonic stem cell, a cloned stem cell, a parthenogenesis derived cell, a cell reprogrammed to possess totipotent properties, or a primordial germ cell; (b) pluripotent cell such as a hematopoietic stem cell, an adipose derived stem cell, a mesenchymal stem cell, a cord blood stem cell, a placentally derived stem cell, an exfoliated tooth derived stem cells, a hair follicle stem cell or a neural stem cell; and/or (c) a tissue specific progenitor cell such as a precursor cell for the neuronal, hepatic, nephrogenic, adipogenic, osteoblastic, osteoclastic, alveolar, cardiac, intestinal, or endothelial lineage. The cells can be derived, for example, from tissues such as pancreatic tissue, liver tissue, smooth muscle tissue, striated muscle tissue, cardiac muscle tissue, bone tissue, bone marrow tissue, bone spongy tissue, cartilage tissue, liver tissue, pancreas tissue, pancreatic ductal tissue, spleen tissue, thymus tissue, Peyer's patch tissue, lymph nodes tissue, thyroid tissue, epidermis tissue, dermis tissue, subcutaneous tissue, heart tissue, lung tissue, vascular tissue, endothelial tissue, blood cells, bladder tissue, kidney tissue, digestive tract tissue, esophagus tissue, stomach tissue, small intestine tissue, large intestine tissue, adipose tissue, uterus tissue, eye tissue, lung tissue, testicular tissue, ovarian tissue, prostate tissue, connective tissue, endocrine tissue, and/or mesentery tissue.

As used herein, the terms “slide,” “scaffold,” “support,” “support slide,” or “platform,” used in the context of a structure for supporting liquid crystal matrices and/or extracellular matrices, refers to a structure capable of supporting liquid crystals, or any other matrix, and cells and/or tissues contained therewith. Such slides or supports have various contemplated surfaces, and/or are composed of materials, which include, but are not limited to, glass, metal, plastic, and/or materials coated with polymers for binding and/or immobilization of a liquid crystal matrix of extracellular matrix. The polymers include, but are not limited to, e.g., poly(N-isopropylacrylamide) (PIPAAm), isopropylacrylamide butyl methacrylate copolymer (IBc), butyl methacrylate (BMA), poly-NIPAAm-co-AAc-co-tBAAm (IAtB), N,N-dimethylaminopropylacrylamide (DMAPAAm), poly(N-acryloylpiperidine)-cysteamine (pAP), PIPAAM-carboxymethyl dextran benzylamide sulfonate/sulfate (PIPAAm-CMDBS), or N,N-methylene-bis-acrylamide cross-linked polymer, PIPAAm-PEG, or any combinations thereof.

As used herein, the term “somatic cell” refers to any cell other than germ cells, such as, but not limited to, an egg, a sperm, or the like, which does not directly transfer its DNA to the next generation. Typically, somatic cells have limited or no pluripotency. Somatic cells used herein may be naturally-occurring or genetically-modified.

As used herein, the term “substantially purified cell,” “isolated cell,” “isolated population of cells,” or “single population of cells” refers to is a cell or cell population that is essentially free of other cell types, e.g., completely free of, substantially free of, or at least reduced from, non-identical cell types or other cells at a particular stage of differentiation. A substantially purified cell also refers to a cell which has been separated from other cell types with which it is normally associated in its naturally occurring state. In some instances, a population of substantially purified cells refers to a homogenous population of cells. In other instances, this term refers simply to cell that have been separated from the cells with which they are naturally associated in their natural state. In illustrative embodiments, an “isolated cell population” constitutes at least about 50%, at least about 75%, at least about 80%, at least about 85%, at least about 90%, at least about 95%, or at least about 99% of a sample containing the identified cell type.

As used herein, the term “wettability” or “wetting” refers to the ability of a substance to maintain surface contact with a different substance or surface. Surface contact results from intermolecular interactions between a substance and the contacted surface. Wetting, and the surface forces that control wetting, are also responsible for other related effects, including capillary action or capillary effects. For example, when a cell adheres to a surface the wettability, or degree of wetting, can be calculated in terms of the force balance between the adhesive and cohesive forces. Wettability can be altered by, for example, applying a low voltage electric field to a substance or surface, which, thereby, may affect the adhesive and cohesive forces between the substance and surface.

### Methods of Cell Sorting and Related Applications

Researchers often need to distinguish between various cell types within a sample. To facilitate separation of specific cell types, it may be necessary to interrogate a single cell or a population of cells based on the expression of an endogenous surface antigen or marker. These markers are typically detected via antibody binding. For certain cell types, however, such markers have yet to be elucidated or the markers that have been identified lack sufficient specificity. As such, one of the only avenues for detection and separation of certain cell types is through the introduction of an ascertainable genetic marker under the control of a lineage-specific promoter. Therefore, it can be difficult to efficiently detect and separate undifferentiated cells, i.e., stem cells.

A sample containing undifferentiated stem cells, moreover, rarely includes a uniform population of cells, but rather, a mixture of cells with varying potential for differentiation. In concert with the progressive stages of cellular differentiation, expression of stage-specific cell surface molecules can facilitate the identification of stem cell populations. Nevertheless, for the myriad of stem cell populations that exist, such markers are neither ubiquitous nor entirely reliable.

The cell sorting methods and apparatuses disclosed herein allow for the separation of different cell types and provide, for example, a tool for distinguishing between the stages of cellular differentiation. The biochemical and physical properties of different cell types impart a mechanism for analyzing and discriminating between cell types that possess at least one specific and/or non-redundant marker or characteristic. For instance, marked changes in cell surface antigens appear at the onset of apoptosis, mitosis, meiosis, cell division, and at varying stages of cellular differentiation. Detecting these changes is important for sorting and collecting different cell types, including undifferentiated cells, i.e., stem cells, which can then be exploited for tissue engineering and therapeutic applications. In this regard, if sufficient purity is not realized and non-specific cell contamination occurs, tissue regeneration and/or transplantation of stem cells into a patient may generate an undesirable toxic response in the host. As such, accurate allogenic separation of cell types is required for stem cell transplantation and tissue regeneration.

Current cell and stem cell sorting methods, such as, e.g., flow cytometry, allow for the isolation of cell specific populations, but are nonetheless dependent upon the expression of a specific surface marker for positive or negative cell selection. With positive selection techniques, the desired cells are labeled with antibodies and removed from the remaining unlabeled cells, which are not wanted. In negative selection, the unwanted cells are labeled and removed. Accordingly, the efficacy of these assays hinge on the specificity of an antibody that recognizes a cell-specific marker.

Regardless of which selection technique is employed, the use of antibodies or other labels still requires an endogenous marker which may not be practical for certain applications. In fact, in some instances, a suitable endogenous marker is unavailable and alternative methods for cell selection are required, e.g., the introduction of an exogenous genetic marker under the control of a promoter requiring differentiation-specific factors for activation. Although accepted stem cell markers are available, and include, but are not limited to, FLK-1, AC133, CD34, c-kit, CXCR-4, Oct-4, Rex-1, CD9, CD13, CD29, CD44, CD166, CD90, CD105, SH-3, SH-4, TRA-1-60, TRA-1-81, SSEA-4, and Sox-2, the use of these markers prior to tissue generation or transplantation may not be practical because the use of labels may confound cellular activity.

Density gradient centrifugation and morphological discrimination are other means for distinguishing cell types, but these techniques are less efficient than positive selection because some percentage of stem cells are pelleted and/or eliminated during such a procedure. Imaging flow cytometry, which uses light scattering techniques to determine cell size and granularity, is another mechanism for separating cells. Nevertheless, challenges associated with flow cytometry are ubiquitous and include, e.g., imaging sensitivity, spatial resolution, combinatorial imaging modes, and cell flow-stream capture.

Moreover, in addition to the limits posed by “tagging” specific markers with fluorescently labeled or magnetically bound antibodies, fluorescence-activated cell sorting (FACS) and magnetic-activated cell sorting (MACS) techniques are not typically amenable to high throughput applications. In fact, conventional cell sorting methods are typically only capable of processing up to 3,000 cells/second. Although sorting purities are sufficient for these methods at approximately 95%, the typical yield of FACS and MACS is relatively low, e.g., 50-70%. These rates do not provide for the large number of stem cells required for tissue engineering and stem cell transplant applications.

### Liquid Crystal Cell Sorting

In order to address these considerations, among others, the present disclosure provides a method of cell sorting which does not rely on antibodies or exogenous labels for distinguishing between different cell types or various stages of differentiation. In this respect, the present disclosure is based on the discovery that cells can be sorted by measuring the cellular response to a change in liquid crystal surface wettability. Anisotropic liquid crystal matrices are capable of accurately communicating micro-scale fluctuations of cell surface interactions unique to a specific cell type. See, e.g., Lockwood, N., Thermotropic liquid crystals as substrates for imaging the reorganization of matrigel by human embryonic stem cells. Advanced Functional Materials. Vol. 16, 618-624 (2006). The reorganization of nematic liquid crystals is highly sensitive and the differential forces emanating from cell specific adhesion can be optoelectrically detected. See, e.g., Jang, et. al., Using liquid crystals to report membrane proteins captured by affinity microcontact printing from cell lysates and membrane extracts. JAGS. Vol., 127 8912-8913 (2005). In this way, the present diclsoure provides liquid crystal based cell interrogation as an avenue for conjugate-free cell sorting and related tissue engineering applications.

In one aspect, the present disclosure includes a method for cell sorting, wherein cells are deposited on a liquid crystal matrix. In illustrative embodiments, the deposited cells affect a change in the liquid crystal alignment which is subsequently transferred through the liquid crystal bulk, detected with an optoelectric device, and recorded. Typically, such change in the liquid crystal orientation depends upon the adhesion of cells at the liquid crystal interface. In this regard, the stage of cellular differentiation or the type of cell effects the strength of adhesion. Moreover, the type of surface and its concomitant wettability are factors that influence bond strength and cellular adhesion. See, e.g., Chiu et al., Electrically surface-driven switchable wettability of liquid crystal/polymer composite film, Applied Physics Letters, Vol. 96, 131902 (1-3) (2010). Accordingly, by altering the wettable surface of liquid crystals, a cell-specific response is induced, which produces a change in the liquid crystal matrix orientation. This change can be detected with an optoelectronic device. Consequently, by measuring the change in liquid crystal matrix orientation, different cell types or cells possessing properties unique to a stage of cellular differentiation are separated into distinct populations.

Liquid crystal is known to reorganize under the influence of stresses comparable in magnitude to those transmitted from cells to their environments. See, e.g., Lockwood (2006). Following the addition of one or more cell types, liquid crystal reorientation provides for a measureable change at the liquid crystal interface, i.e., “anchoring.” Liquid crystal anchoring is highly sensitive to the nature of the interactions between a restricting interface and mesogens, i.e., the fundamental liquid crystal unit imparting structural order. For example, it has been shown that liquid crystal orientation is coupled to the presence and polarity of phospholipid and protein interfaces. See, e.g., Brake et al., Biomolecular Interactions at Phospholipid-Decorated Surfaces of Liquid Crystals. Science. Vol. 302(5653), 2094-2098 (2003). Furthermore, the change in cellular adherence and/or the degree of adherence, at the liquid crystal interface, is associated with cell type and/or stage of differentiation. See, e.g., Lockwood (2006). Other associations such as, e.g., the number and type of adhesion ligands, including their distribution on the cell surface, are also associated with cell type and/or stage of differentiation. As such, following a change in surface wettability at the interface, a cell type or differentiation stage dependent reordering of the liquid crystal occurs.

### Liquid Crystals

Various types of liquid crystals are suitable for use in the context of the present disclosure. Non-limiting examples of these include both nematic and smectic liquid crystals. Other classes of liquid crystals that may be used in accordance with the invention include, but are not limited to, polymeric liquid crystals, lyotropic liquid crystals, thermotropic liquid crystals, columnar liquid crystals, nematic discotic liquid crystals, calamitic nematic liquid crystals, ferroelectric liquid crystals, discoid liquid crystals, and cholesteric liquid crystals. Other examples of liquid crystals that may be used are shown in Table 1.

TABLE 1
Molecular Structure of Suitable Mesogens

| Mesogen | Structure |
|---|---|
| Anisaldazine | 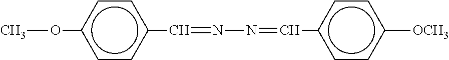 |
| NCB | 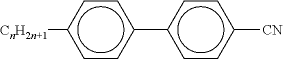 |
| CBOOA | 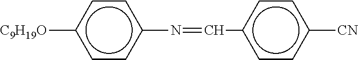 |
| Comp A | 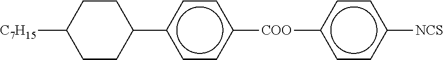 |
| Comp B | 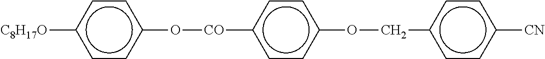 |
| DB₇NO₂ | 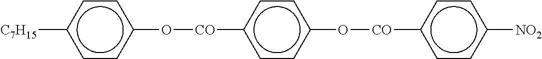 |
| DOBAMBC | 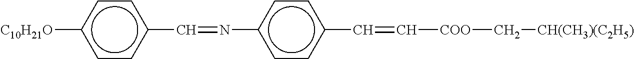 |
| nOm n = 1, m = 4: MBBA n = 1, m = 4: EBBA | 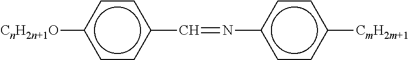 |
| nOBA n = 8:OOBA n = 9: NOBA | 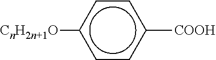 |
| nmOBC | 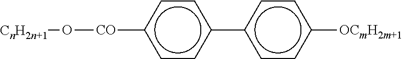 |
| nOBC | 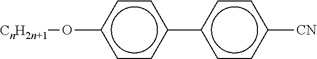 |
| nOSi | 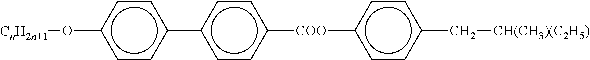 |
| 98P | 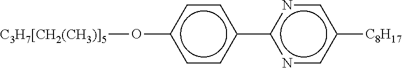 |
| PAA | 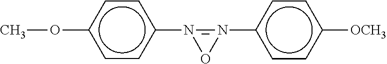 |
| PYP906 | 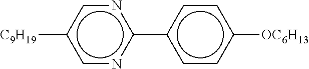 |
| ñSm | 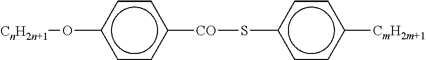 |

In particular, non-limiting examples of specific liquid crystalline matrices include, 4-(3-acryloyloxypropyloxy)-benzoic acid 2-methyl-1,4-phenylene ester; 4-trans-propylcyclohexylcyanobenzene; 4-trans-butylcyclohexylcyanobenzene; 4-trans-pentylcyclohexylcyanobenzene; 4-trans-heptylcyclohexylcyanobenzene; 4-cyano-4′-trans-pentylcyclohexanebiphenyl; 4-trans-propylcyclohexyl-4′-ethylbiphenyl; 4-trans-propylcyclohexyl-4′-propylbiphenyl; 4-ethyl-4′-cyanobiphenyl; 4-propyl-4′-cyanobiphenyl; 4-butyl-4′-cyanobiphenyl; 4-pentyl-4′-cyanobiphenyl; and 4-heptyl-4′-cyanobiphenyl. An extensive listing of liquid crystals suitable for use in the present invention is presented in “Handbook of Liquid Crystal Research” by Peter J. Collings and Jay S. Patel, Oxford University Press, 1997, ISBN 0-19-508442-X. In illustrative embodiments, 4-cyano-4′-pentylbiphenyl or 5CB is employed. Although various types of liquid crystal may be employed, in illustrative embodiments nematic liquid crystal are used.

The sensitivity of a liquid crystal matrix may be improved by doping the liquid crystal with nanocolloid ferroelectric particles. Doping liquid crystals with ferroelectric nanoparticles enhances optical birefringence, dielectric anisotropy, and elastic constants. Accordingly, such nanocolloids can be employed to improve the performance of liquid crystal cell sorting. As such, in illustrative embodiments, ferroelectric nanoparticles are applied to the liquid crystal matrix. See, e.g., Kurochkin et al., “A colloid of ferroelectric nanoparticles in a cholesteric liquid crystal.” J. Opt. A: Pure Appl. Opt., Vol., 11, pp. 2-4 (2009). In other embodiments, the application of ferroelectric nanoparticles occurs prior to altering the liquid crystal matrix wettability. Ferroelectric nanoparticles may be, for example, selected from Sn₂P₂S₆, BaTiO₃, PbTiO₃, lead zirconate titanate (PZT), and combinations thereof.

### Apical Films

In illustrative embodiments, the liquid crystal matrix includes an apical film disposed between the liquid crystal and the deposited cells. In other embodiments, the apical film is composed of a nutrient layer, including, for example, an extracellular matrix (ECM), basement membrane extract, and/or Engelbreth-Holm-Swarm (EHS) matrix, and the like. It will be readily apparent to one of skill in the art that any suitable film can be employed so long as cell proliferation and attachment to the liquid crystal interface is supported. In this regard, when differentiated cells or stem cells are adhered to liquid crystal layered within the apical film, the cells are allowed to self-renew, and for stems cells this regeneration occurs in an undifferentiated manner. In illustrative embodiments, Matrigel™ (BD Biosciences, Franklin Lakes, N.J.) is used for stem cell proliferation and regeneration.

Cell surface adhesion to the apical film, e.g., the ECM, is influenced by the matrices' thickness. The cellular matrix influences the hydrophobicity of the system, and thus, the adherent nature of the cell-liquid crystal complex. In illustrative embodiments, the thickness is adjusted so that the hydrophobic surface of the apical layer is accessible to cells while the liquid crystal matrix is also hydrophobically adherent to the apical film and/or cells deposited thereon. Moreover, in other embodiments, when one or more cell types fail to adhere to the apical film and/or liquid crystal matrix, this information can be used to discriminate different cell types insofar as they are compared to adherent cells.

The thickness of the apical film layer is determined via ellipsometry and subsequently modified if appropriate. In illustrative embodiments, the thickness of the apical layer is about 0.1, 0.25, 0.5, 0.75, 1, 3, 5, 7, 9, 10, 15, 20, 30, 50, 100, 500, or 900 nm to about 0.1, 0.25, 0.5, 0.75, 1, 3, 5, 7, 9, 10, 15, 20, 30, 50, 100, 500, or 900 nm. In other embodiments, the thickness of the apical layer is about 0.1, 0.25, 0.5, 0.75, 1, 3, 5, 7, 9, or 10 nm to about 0.5, 0.75, 1, 3, 5, 7, 9, 10, 15, 20, 30, 50, or 100 nm. In illustrative embodiments, the thickness of the apical layer is about 10 nm.

### Applying Cells

The cells can be deposited on the apical film layer disposed on the liquid crystal matrix using any suitable technique in the art. In illustrative embodiments, the cells are deposited by liquid nozzle spray or polydimethylsiloxane (PDMS) stamp for microcontact printing. In illustrative embodiments, the stamp is prepared using an elastomeric polymer such as PDMS. Such a stamp is prepared, in illustrative embodiments, by pouring a mixture of an elastomer such as Sylgard® 184CA brand PDMS in a master, such as, e.g., a silicon master, with a curing agent in an appropriate curing ratio such as, e.g., a 10:1 ratio of PDMS to curing agent. The width and depth of the relief varies according to the application and any shape can be used to provide surfaces with various regions which contain the cellular and/or apical film layer. In one exemplary application, the width of the relief is 15 μm and the depth of the relief is about 20 μm.

After removal of entrained air bubbles such as by use of an applied vacuum, the mixture is allowed to cure. The stamp is then gently removed and rinsed. The rinsed stamp is then “inked” by placing a small drop of solution, e.g., containing the desired cell or cell population on the stamp. The cells are incubated on the stamp for an appropriate period of time of about 5 seconds to about 15-20 minutes. Subsequently, the PDMS stamp is employed for depositing cells on the apical layer. It will be readily apparent to the skilled artisan that there are various additional methods for cellular application, such as, but not limited to liquid nozzle spray.

### Measurement

Following application of the cells on the apical film layer, an initial measurement of the liquid crystal orientation is performed. In illustrative embodiments, the liquid crystal matrix orientation is measured by optoelectric polarized light microscopy. A polarized light microscope is used to observe the optical orientation, order, reordering, and/or texture formed by light transmitted through the liquid crystal matrix. In illustrative embodiments, images are obtained using a 20× objective lens with a 550 μm field of view between cross-polars. Other powers of magnification, e.g., 10×, can also be used with concomitant fields of view between crossed polarizer, e.g., 1 mm or larger. It will be readily apparent to the skilled artisan that adjusting the power, filed of view, and associated resolution may be altered to suit a desired application.

Images of the optical appearance of liquid crystal matrices may also be captured with a digital camera (C-2020 Z, obtained from Olympus America Inc. (Melville, N.Y.)), which is attached to the polarized light microscope in illustrative embodiments. High quality resolution, e.g., 1600×1200 pixels, at suitable apertures and shutter speeds can be adjusted as necessary. In illustrative embodiments, using, e.g., polarized light or fluorescence imaging, the azimuthal orientation of the liquid crystals is determined by a change in interference colors upon insertion of a quarter-wave plate into the optical path. See, e.g., Brake et al., “Formation and Characterization of Phospholipid Monolayers Spontaneously Assembled at Interfaces between Aqueous Phases and Thermotropic Liquid Crystals.” Langmuir Vol. 21, pp. 2218-2228 (2005).

### Change in Surface Wettability

In one aspect, the present disclosure provides a means for distinguishing between cell types based on a cell-type specific response to an external stimulus. In illustrative embodiments, the stimulus is a change in the wettability of the surface on which the cells are deposited. Wettability can be altered by, for example, applying a low voltage electric field to a substance or surface, which, thereby, effects the adhesive and/or cohesive forces between cells and a surface, e.g., the liquid crystal surface with an ECM apical layer.

Such a change in wettability introduces a “shock” to the cell colony which can be captured via liquid crystal matrix representation or reordering. In illustrative embodiments, the stimulus or shock is manifested mechanically as a sudden change in a measureable cell characteristic. In illustrative embodiments, this characteristic is a transformation in the forces associated with cell-surface adhesion. In other embodiments, the transformation relates to a cell-specific expansion or contractile response to a change in surface wettability. This stimulus induced change also manifests as an electrical shock, e.g., a change in electrostatic attraction/repulsion. In this respect, the liquid crystal matrices are capable of immediately recording the induced change in cellular adhesion to a surface. In short, liquid crystal reordering is a sensitive tool that can detect biological, chemical, electrostatic, and/or mechanical changes, which occurs in less than one second. See, e.g., Evans and Calderwood, Forces and Bond Dynamics in Cell Adhesion, Science. Vol. 316, pp. 1148-1153 (2007).

In illustrative embodiments, the liquid crystal matrix wettability is altered by applying a low voltage electric field of about 0.001, 0.01, 0.05 or 0.1 V/μm to about 0.01, 0.05, 0.1, or about 1.0 V/μm. In other embodiments, the liquid crystal matrix wettability is altered by applying a low voltage electric field of about 0.01 V/μm to about 0.1 V/μm. It will be readily apparent to the skilled artisan that various voltages can be applied and adjusted to achieve a desired result, e.g., suitable separation of cells. The cellular response to the application of the low voltage electric field can be detected as noted above, e.g., measuring a change in liquid crystal matrix orientation by optoelectronic detecting. In illustrative embodiments, the optoelectronic detecting is by polarized light microscopy.

Furthermore, the change in wettability and the concomitant cellular response can be measured over a specific time course. In illustrative embodiments, the time course includes about 1, 2, 3, 4, 5, 6, 7, 8, 9, or 10, to about 5, 10, 20, 30, 40, or 50 time points. In an illustrative embodiment, 2 or more time points are used for measuring the cell response to a change in wettability. In other embodiments, a low voltage electric field is applied at one or more time points intervals of about 0.0001, 0.001, 0.01, 0.1, 0.5, 1, 5, 10, 30, 45, 60, 120, 240, or 480 seconds to about 0.01, 0.1, 0.5, 1, 2, 3, 4, 5, 6, 7, 8, 9, 10, 20, or 30 seconds or minutes. In illustrative embodiments, a low voltage electric field is applied at one or more time points intervals of about 0.01, 0.1, 0.5, 1, 5, 10, 30, or 60 seconds to about 0.1, 1, 2, 3, or 4 seconds or minutes. See, e.g., Evans et al., “Forces and Bond Dynamics in Cell Adhesion.” Science Vol. 316, pp. 1148-1153 (2007).

### Cell Sorting and Collection

Cell-type specific populations can subsequently be sorted and collected using techniques known in the art. For example, a computerized system including hardware and software for analyzing liquid crystal orientation and characterizing cells may be employed. Such an apparatus may include light sources, such as a laser, as well as optics and filters to present a laser light to the sample for dissecting cells from the liquid crystal matrix and/or obtaining signals from the sample. Fluid flow collection systems may also be employed in certain embodiments. The optics can be fiber optics for increased compactness. The system can also comprise an inverted and phase contrast microscope, CCD camera, compact fiber based spectrometers, computer, software, and a flow cell sample collection system. The computer and the software may be automated to obtain the liquid crystal orientation and reordering data from the sample, perform an analysis on the procured data, and compare the results to a database to characterize or identify the cell.

### Reference Database

In illustrative embodiments, a spectra of liquid crystal orientations, for a plurality of cells, is obtained in order to generate a reference database. Such a spectra of the plurality of the cells can be averaged to provide a mean reordering orientation for one or more cell types. Once a reference spectrum has been obtained for a particular cell type, that spectrum can be compared to spectra from unknown cell types in order to identify the unknown cells. Statistical methods can be used to set thresholds for determining when the orientational change of a cell in an unknown sample can be considered to be different than or similar to a reference level. In addition, statistics can be used to determine the validity of the difference or similarity observed between an unknown reordered phase of the liquid crystals and the reference level. Useful statistical analysis methods are described in L. D. Fisher & G. vanBelle, Biostatistics: A Methodology for the Health Sciences (Wiley-Interscience, NY, 1993). For instance, confidence (“p”) values can be calculated using an unpaired 2-tailed t test, with a difference between samples deemed significant if the p value is less than or equal to 0.05.

In illustrative embodiments, liquid crystal reordering is combined with other optical characteristics of cells in order to enhance the identification and sorting of cell populations. In illustrative embodiments, the additional optical characteristics are, for example, forward scattering, side scattering, and Raleigh scattering of light applied from light source. A difference between the present methods and conventional flow cytometry is that the addition of liquid crystal reordering allows for the addition of one or more discriminatory dimensions, which makes the segregation of cell populations more effective and efficient. As such, by combining one or more conventional techniques with the present technology, increased cell sorting specificity may be realized. In illustrative embodiments, reference information is gathered and stored using a combination of methods.

### Methods for the Identification of Cell Types or Stages of Differentiation

In illustrative embodiments, the present disclosure provides methods for identifying and sorting cells based on their response to a low voltage shock. These methods provide an advantage over conventional cell sorting methods that are based on negative selection because negative selection methods, such as centrifugation, do not efficiently recover all of the cells of interest. Moreover, the present methods provide an advantage over cell sorting methods that rely on labels, which exert stress on the cells. The sorting methods of the present disclosure are rapid, as after the cells are adhered to the liquid crystal/ECM surface the measuring of the differential cell response can occur in a few seconds. As such, the present methods provide greater numbers of enriched, separated cells with higher purity than conventional methods.

In illustrative embodiments, a single cell or a collection of cells can be analyzed. The cell can be a single cell organism, such as a bacterium, a yeast, and the like, or it can be obtained from a subject such as a human, plant, fish, animal, and the like. The cells from a sample or subject can include, but are not limited to, a normal cell, a cancer cell, mutated cells, altered cells, infected cells, diseased cells, virus infected cells, morphogenic cells, an engineered cell (e.g., recombinant cells, synthetic cells, and/or hybrid cells, etc.), stem cells, mammalian cells, bacterial cells, insect cells, human cells, plant cells, skin cells, muscle cells, epithelial cells, endothelial cells, umbilical vessel cells, corneal cells, cardiomyocytes, aortic cells, corneal epithelial cells, aortic endothelial cells, fibroblasts, hair cells, keratinocytes, melanocytes, adipose cells, bone cells, osteoblasts, airway cells, microvascular cells, mammary cells, vascular cells, chondrocytes, and placental cells, or any combination thereof.

Stem cells are undifferentiated cells. These cells retain the ability to divide throughout life and give rise to both new stem cells and to differentiated or specialized cells which replace dead or dying cells. Thus, stem cells contribute to the body's ability to renew and repair its tissues, because unlike differentiated or mature cells, stem cells are not permanently committed to any specific cellular tropism. Stem cells are recognized as being “multipotent” meaning that such cells are restricted to a specific lineage, or “totipotent,” which encompasses “pluripotent” cells, both of which possesses the ability to differentiate into more than one type of specialized mature cell. Somatic stem cells or “adult stem cells” are cells with these characteristics that are derived from non-embryonic sources. Such origins may include, inter alia, neonatal cells and umbilical cord blood.

Adult stem cells arise from many different tissue types. Studies have identified bone marrow stem cells, peripheral blood stem cell, neuronal stem cells, muscle stem cells, liver stem cells, pancreatic stem cells, corneal limbal stem cells, mammary stem cells, salivary gland stem cells, stomach stem cells, skin stem cells, tendon stem cells, synovial membrane stem cells, heart stem cells, cartilage stem cells, thymic progenitor stem cells, dental pulp stem cells, adipose derived stem cells, umbilical cord blood and mesenchymal stem cells, amniotic stem cells, mesangioblasts, and colon stem cells. Because many adult stem cells are multipotent, but not pluripotent, exploitation of adult stem cells may depend on the ability to readily identify and isolate stem cells of different types.

In one aspect, the present methods are used to sort a heterogeneous population of cells into its constituent cell types. Thus, a substantially homogenous cell population of interest can be obtained. In an illustrative embodiment, the cell population of interest is a population of stem cells. The cells that are not in the population of interest can be destroyed. For example, a laser used for cell removal and collection can also be used to kill the cell, such as, for example, by increasing the power output, changing the wavelength of the laser where it is lethal to the cell, and the like. In another aspect, the cells that are not in the population of interest can be sorted from the other cells, similar to fluorescence flow cytometry. For example, after the change in wettability, a laser can be used to push the normal cells into a container for the cells of interest, while the other cells can be collected into a separate container. This can also be performed using a fluid flow chamber.

In one aspect, the present methods are used to isolate substantially homogenous populations of stem cells for use in tissue engineering and/or therapy. In illustrative embodiments, stem cells are isolated. Stem cells may be isolated from umbilical cord blood from a newborn. The cord blood material is usually discarded at birth, however, cord blood can be used for either autologous or allogenic stem cell replacement. Enrichment of the cord blood stem cells by the characteristic reordering of liquid crystals to which the cells are bound, and sorting based on the analysis, allows for a smaller amount of material to be stored, which can be more easily given back to the patient or another host. In yet another embodiment, adult stem cells are isolated from various organs. For example, stem cells from heart, liver, neural tissue, bone marrow, and the like, have small subpopulations of immortal stem cells which may be manipulated ex vivo and then can be reintroduced into a patient in order to regrow or repopulate a damaged tissue. The methods described above can be used to enrich these extremely rare stem cells so that they may be used for cell therapy applications.

In suitable embodiments, the present methods are employed for detecting diseased cells, such as cancer cells, in a sample. In illustrative embodiments, the diseased cells include blood cell malignancies. Some representative blood cell malignancies include lymphomas, leukemias, and myelomas. Other blood cell malignancies are known in the art. For example, a blood sample may be obtained from a patient having or suspected of having a blood cell disorder. The liquid crystal orientation spectrum of the cell is then compared to a database of previously generated spectra to determine if the identified pattern imparts the presence of disease, e.g., a malignant cell spectra. The presence of malignant cells in a sample can be employed for identifying patient populations and in the diagnosis of blood cell disorders.

The cells purified or isolated in the methods of the present disclosure can be utilized for repairing or regenerating a tissue or differentiated cell lineage in a subject. The method includes obtaining a differentiated cell as described herein and administering the cell to a subject (e.g., a subject having a myocardial infarction, congestive heart failure, stroke, ischemia, peripheral vascular disease, alcoholic liver disease, cirrhosis, Parkinson's disease, Alzheimer's disease, diabetes, cancer, arthritis, wound healing, immunodeficiency, aplastic anemia, anemia, and genetic disorders) and similar diseases, where an increase or replacement of a particular cell type/tissue or cellular de-differentiation is desirable. In illustrative embodiments, the subject has damage to the tissue or organ, and the administering provides a dose of cells sufficient to increase a biological function of the tissue or organ or to increase the number of cell present in the tissue or organ. In other embodiments, the subject has a disease, disorder, or condition, and wherein the administering provides a dose of cells sufficient to ameliorate or stabilize the disease, disorder, or condition. In yet another embodiment, the subject has a deficiency of a particular cell type, such as a circulating blood cell type and wherein the administering restores such circulating blood cells.

In another aspect, the methods described above can be used for the detection, identification and/or quantification of single cell organisms, such as, for example, bacteria, yeast, and the like. In particular, the methods can be used for the detection of organisms of specific bacterial genus, species or serotype, in isolated form or as contaminants in environmental or forensic samples, or in foodstuff. A wide variety of single cells can be assessed with these methods. These include for example gram-positive bacteria, gram-negative bacteria, fungi, viruses, etc. Thus, the methods described above can be used to identify pathogens, including, but not limited to, Staphylococcus aureus, Listeria monocytogenes, Bacillus cereus, Salmonella, Cholera, Campylobacter jejuni, and E. coli. It will be seen by those skilled in the art however that other types of cells can be identified using the methods described above.

The detection of single cell organisms can be used, for example, for an early diagnosis of patients suffering from a pathogen infection. Thus, according to the present methods, there is provided a process for the detection of pathogens in the blood, such as bacteria, fungi and viruses. In illustrative embodiments, the harmful (pathogenic) cells can be sorted from the normal cells, similar to fluorescence flow cytometry. The methods described above can be used to indicate the presence of microbes responsible for disease, and if present, the harmful bacteria can be destroyed.

Following the separation of various cell types, cell culturing is performed and modified, as desired, for suitable applications requiring a particular cell density and/or confluence, which can be for about 1, 2, 3, 4, 5, 6, 7, 8, 9, 10, 11, 12, 13, 14, 15, 16, 17, 18, 19, 20, 25, 30, 35, 40, or 50 days. In illustrative embodiments, the cells are cultured for about 13, 14, 15, 16, 17, or 18 days. In illustrative embodiments, the cells are cultured until a desired cell density is attained. In illustrative embodiments, the cells are cultured until they are grown to confluence. The amount of time required for cell culturing depends upon the type of cell cultured. Cell culture media, e.g., DMEM, can be replenished as required for suitable cell and tissue growth.

Furthermore, following the separation of purified cell-types, a variety of cell or tissue applications can be implemented in accord with the present methods. These applications include, but are not limited to, cell culturing, producing cell-layers that are suitable for cell and tissue grafting, skin-grafting, allografting, wound healing grafts, skin replacement, ocular reconstruction, liver tissue reconstruction, cardiac patching, or bladder augmentation, or any combination thereof. Additionally, one or more cell-layers, cells, tissues, and/or other biological outgrowths can be produced by using cell-type specific populations or differentiation stage specific cell populations of cells. See, e.g., Fiegel, et al., Fetal and adult liver stem cells for liver regeneration and tissue engineering. J. Cell. Mol. Med. Vol 10 (3) pp. 577-587 (2006).

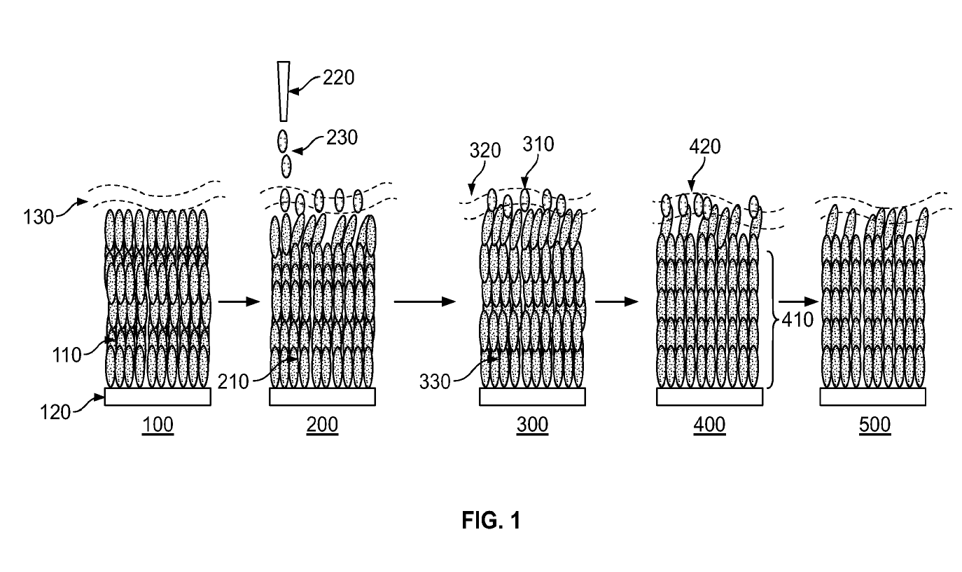

FIG. 1 shows an illustrative embodiment of a method for cell sorting that is used in accordance with the present disclosure. In operation 100, liquid crystal 110 is applied to a support slide 120 with extracellular matrix film 130. In operation 100, the liquid crystal 110 is aligned in the nematic phase. In operation 200, the liquid crystal 210 is positioned under a cell nozzle 220, which dispenses a population of cells 230. In operation 300, the cells 310 initially reorganize the extracellular matrix film 320 and the liquid crystal 330 reorganizes based on the film reorganization 320. In operation 300, the liquid crystal reorganization 330 is transmitted through the bulk and is recorded optoelectronically. In operation 400, the surface wettability of the liquid crystal 410 is switched to a predetermined value. In operation 400, the cell response 420 to the change in wettability 410 is also recorded optoelectronically. In operation 500, cells are removed from the liquid crystal matrix using liquid flow or laser dissection and the wettability is restored back to its original phase.

### Apparatuses and Devices for Cell Sorting

In one aspect, the present disclosure provides a cell sorting apparatus which includes a rotatable carousel with one or more support slides or platforms, wherein the one or more platforms include a liquid crystal matrix configured to receive cells. In illustrative embodiments, the platforms are made of any suitable material so long as the platform provides a foundation for liquid crystal attachment. For example, a wide variety of materials may be used as supports in the devices and methods of the present invention as will be apparent to those skilled in the art. In illustrative embodiments, support slides or platforms are composed of, but are not limited to, metals, polymers, and silica-containing materials such as glass and quartz. Examples of polymeric supports include, but are not limited to, polystyrene, polycarbonates, and polymethyl methacrylate. Other materials suitable for use as supports include metal oxides such as, but not limited to, indium oxide, tin oxide, and magnesium oxide and metals such as, but not limited to, gold, silver, copper, nickel, palladium, and platinum. Still other materials that may be used as supports include cellulosic materials such as nitrocellulose, wood, paper, and cardboard, and sol-gel materials. In some embodiments, supports include glass, quartz, and silica, and in illustrative embodiments supports include metals, glass slides, glass plates, and silica wafers. Such supports are cleaned prior to use where applicable. For example, glass slides and plates may be cleaned by treatment in “piranha solution” (70% H₂SO₄/30% H₂O₂) for 1 hour and then rinsed with deionized water before drying under a stream of nitrogen.

The slides of the present disclosure facilitate nematic liquid crystal adherence of a variety of liquid crystal matrices, including, but not limited to, polymeric liquid crystals, lyotropic liquid crystals, thermotropic liquid crystals, columnar liquid crystals, nematic discotic liquid crystals, calamitic nematic liquid crystals, ferroelectric liquid crystals, discoid liquid crystals, and cholesteric liquid crystals. Other examples of liquid crystals that may be used are shown in Table 1 above.

Other, non-limiting examples of specific liquid crystalline matrices, include, 4-(3-acryloyloxypropyloxy)-benzoic acid 2-methyl-1,4-phenylene ester; 4-trans-propylcyclohexylcyanobenzene; 4-trans-butylcyclohexylcyanobenzene; 4-trans-pentylcyclohexylcyanobenzene; 4-trans-heptylcyclohexylcyanobenzene; 4-cyano-4′-trans-pentylcyclohexanebiphenyl; 4-trans-propylcyclohexyl-4′-ethylbiphenyl; 4-trans-propylcyclohexyl-4′-propylbiphenyl; 4-ethyl-4′-cyanobiphenyl; 4-propyl-4′-cyanobiphenyl; 4-butyl-4′-cyanobiphenyl; 4-pentyl-4′-cyanobiphenyl; and 4-heptyl-4′-cyanobiphenyl. An extensive listing of liquid crystals suitable for use in the present invention is presented in “Handbook of Liquid Crystal Research” by Peter J. Collings and Jay S. Patel, Oxford University Press, 1997, ISBN 0-19-508442-X. In illustrative embodiments, 4-cyano-4′-pentylbiphenyl or 5CB is employed.

The liquid crystal matrices may also be sensitized by doping with nanocolloid ferroelectric particles, as described above. Ferroelectric nanoparticles may be, for example, selected from Sn₂P₂S₆, BaTiO₃, PbTiO₃, and lead zirconate titanate (PZT). In accord with the methods of the present disclosure, the apparatus provides for an apical film disposed on the liquid crystal matrix. The apical film is composed of a nutrient layer, including, for example, an extracellular matrix, basement membrane extract, and/or Engelbreth-Holm-Swarm (EHS) matrix, and the like. It will be readily apparent to one of skill in the art that any suitable film can be employed so long as cell attachment, and optionally cell proliferation, to the liquid crystal interface is supported. In this regard, cell attachment may occur about 0.001, 0.001, 0.01, 0.1, 0.5, 1, 5, 10, 60, 120, 240, or 480 seconds to about 1, 2, 3, 5, 10, 30, 50, 100 or 500 minutes or hours. See, e.g., Evans et al., “Forces and Bond Dynamics in Cell Adhesion.” Science Vol. 316, pp. 1148-1153, FIG. 4, (2007). This layer can be added to the liquid crystals after the liquid crystals have been applied to the support slides. Alternatively, the apical layer can be applied to the slides in concert with the liquid crystals.

The thickness of the apical film layer can be determined via ellipsometry and modified if desired. In one embodiment the thickness of the apical layer is about 0.1, 0.25, 0.5, 0.75, 1, 3, 5, 7, 9, 10, 15, 20, 30, 50, 100, 500, or 900 nm to about 0.1, 0.25, 0.5, 0.75, 1, 3, 5, 7, 9, 10, 15, 20, 30, 50, 100, 500, or 900 nm. In another embodiment the thickness of the apical layer is about 0.1, 0.25, 0.5, 0.75, 1, 3, 5, 7, 9, or 10 nm to about 0.5, 0.75, 1, 3, 5, 7, 9, 10, 15, 20, 30, 50, or 100 nm. In illustrative embodiments the thickness of the apical layer is about 10 nm.

The apparatus of the present disclosure may also entail an attached or separate electric source capable of providing a low voltage electric field to the one or more platforms with the liquid crystal matrix. The electric source device is not limited to any specific device, so long as the generated voltage can effectuate a transition in the wettability of a tunable surface. Piezoelectric liquid crystals with ferroelectric nanoparticle, as disclosed herein, are suitable substrates with tunable wettability. In illustrative embodiments, Atomic Force Microscopy (AFM) is employed for measuring and/or applying the electric filed voltage to the liquid crystal matrix, while concomitantly detecting changes in liquid crystal orientation or wettability related thereto. See, e.g., Chiu et al. (2010).

In illustrative embodiments, the liquid crystal matrix wettability is altered by applying a low voltage electric field of about 0.001, 0.01, 0.05 or 0.1 V/μm to about 0.01, 0.05, 0.1, or about 1.0 V/μm. In other embodiments, the liquid crystal matrix wettability is altered by applying a low voltage electric field of about 0.01 V/μm to about 0.1 V/μm. It will be readily apparent to the skilled artisan that various voltages can be applied and adjusted to achieve a desired result, e.g., suitable separation of cells. The cellular response to the application of the low voltage electric field can be detected as noted above, e.g., measuring a change in liquid crystal matrix orientation by optoelectronic detecting. In illustrative embodiments, the optoelectronic detecting is by polarized light microscopy.

In illustrative embodiments, the apparatus of the present disclosure includes an optoelectronic device configured to detect one or more liquid crystal matrix orientations. As described above, a polarizable light microscope is used to optoelectronically detect changes in liquid crystal orientation. In illustrative embodiments, an atomic force microscope is employed. Reordered liquid crystals, i.e., after depositing cells and subsequently altering the wettability of the liquid crystals, may also be detected using an optoelectronic device, such as, e.g., a polarizable light microscope or an atomic force microscope.

In addition, for illustrative embodiments, the apparatus of the present disclosure includes a cell dispenser. In illustrative embodiments, the cell dispenser has a spray nozzle. The spray nozzle, can be any appropriate cell dispenser known in the art, such that an appropriate volume and/or density of cells are applied to the support slides with liquid crystal matrix and apical film. In illustrative embodiments, polydimethylsiloxane (PDMS) stamp application of cells is provided by the present disclosure. The skilled artisan will readily recognize that many different cell dispensing means are suitable for use with the present disclosure. For example, many cell dispenser and printing devices suitable for use are produce by Discovery Scientific (Vancouver, BC).

In illustrative embodiments, the cells are deposited by employing liquid nozzle spray or polydimethylsiloxane (PDMS) stamp for microcontact printing. In such embodiments, the stamp is prepared using an elastomeric polymer such as PDMS. Such a stamp may be prepared by pouring a mixture of an elastomer such as Sylgard® 184CA brand PDMS in a master, such as, e.g., a silicon master, with a curing agent in an appropriate curing ratio such as, e.g., a 10:1 ratio of PDMS to curing agent. The width and depth of the relief may vary according to the application and any shape may be used to provide surfaces with various regions which contain the redox-active layer. In one application, the width of the relief is 15 μm and the depth of the relief is about 20 μm.

In one aspect, the disclosure provides an apparatus for analyzing one or more cell types and sorting the cells based on distinguishing characteristic or properties. In illustrative embodiments, the apparatus includes light sources, such as a laser, as well as optics and filters to present the laser light to the sample and facilitate collection of sorted cells. The optics can be fiber optics for increased compactness. The apparatus can also comprise an inverted and phase contrast microscope, atomic force microscope, CCD camera, compact fiber based spectrometers, computer, software, and a flow cell sample collection system. The computer and the software may be automated to obtain one or more liquid crystal orientations and perform an analysis on the acquired data. Subsequently, the results can be manually or automatically compared to a known, derived, or empirical database to characterize or identify the cell.

In illustrative embodiments, the apparatus of the present disclosure provides a mechanism for removing the sorted cells from the liquid crystals matrix and accompanying apical film. In illustrative embodiments, the cells are removed by fluid flow or by laser dissection. These methods are well known in the art and can be adapted or modified for a desired application. Furthermore, the dislodged or removed cells can be collected in one or more collection vessels composed of material suitable for cell capture and transfer, e.g., polystyrene.

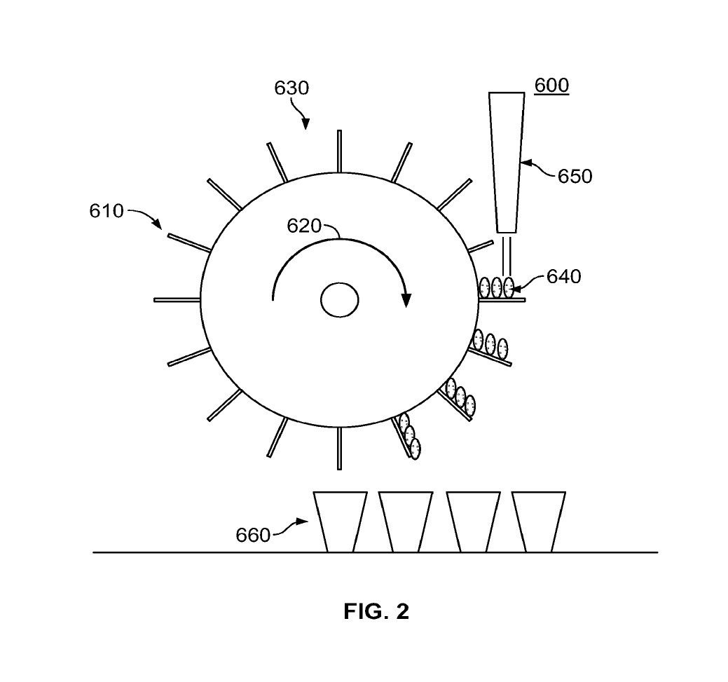

With reference to FIG. 2, apparatus 600 for cell sorting is shown in accordance with an illustrative embodiment. Cell sorting apparatus 600 includes one or more liquid crystal platforms or support slides 610. The cell sorting apparatus 600 also includes a rotatable carousel 620 having one or more apertures such that the one or more apertures receive the one or more liquid crystal platforms or support slides 610. An electrically connected low voltage electric field source is optionally connected to the one or more platforms 610 or rotatable carousel 620. Liquid crystal matrix 630 is configured to receive differentiated or undifferentiated cells 640 disposed on the one or more liquid crystal platforms or support slides 610. The cell sorting apparatus 600 further includes a cell spray nozzle or stamp 650 for cell application to the liquid crystal matrix 630. Vessels or collection containers 660 are provided for collecting progressively differentiated cells. Cell sorting apparatus 600 can also include an attached or removable optoelectronic device configured to measure liquid crystal matrix orientation.

Different and additional components can also be incorporated into cell sorting apparatus 600, in illustrative embodiments. For example, in particular embodiments, the apparatus of the present disclosure also includes, but is not limited to including, a computing system with one or more input interfaces, a communication interface, computer-readable medium, an output interface, a processor, a data processing application, a display, and a printer. Different and additional components may be incorporated into the apparatus for modification of apparatus 600 for a desired application. In this regard, computer-readable medium is an electronic holding place or storage for information so that the information can be accessed by a processor as known to those skilled in the art. Computer-readable medium may include, but is not limited to, any type of random access memory (RAM), any type of read only memory (ROM), any type of flash memory, etc. such as magnetic storage devices, e.g., hard disk, floppy disk, magnetic strips, etc., optical disks, e.g., CD, DVD, etc., smart cards, flash memory devices, etc. Such a computing system may have one or more computer-readable media that use the same or a different memory media technology. In illustrative embodiments, the computing system may include a plurality of processors that use the same or a different processing technology for discriminating cells based on cell type or differentiation stage via liquid crystal matrix reordering.

A fluorescence detector may optionally be included in the cell sorting apparatus 600. In this respect, a fluorescence detection system such as a fluorometer, etc. is not required, but can serve as a control for the methods and apparatuses of the present disclosure. Sample analysis may include polarized light microscopy, such that the light source produces sufficient light energy to generate detect differential patterns or orientations in the liquid crystals of the present disclosure. In illustrative embodiments, the light source for use with the methods will avoid damage to biological materials, such as cells. By choosing wavelengths in ranges where the absorption by cellular components is minimized, the deleterious effects of heating can be avoided. However, a light having a wavelength generally considered to be damaging to biological materials can be used, such as where the illumination is for a short period of time and where deleterious absorption of energy does not occur. In illustrative embodiments, the light sources will be coherent light sources. Typically, the coherent light source will be a laser. However, non-coherent sources may be utilized. Furthermore, if there is more than one light source in the system, these sources can be coherent or incoherent with respect to each other.

In illustrative embodiments, the apparatus of the present disclosure is combined with other techniques known in the art that are suitable for separating differentiated cells or stem cells. This is beneficial when first performing the cell sorting methods of the present disclosure insofar as reference samples can be generated, as detailed above. Conventional methods for sorting stem cells may include, for example, antibody cell panning, fluorescence activated cell sorting (FACS) or magnet activated cell sorting (MACS). Such methods allow for the isolation of cells possessing one or more desired stem cell markers, while concomitantly or separately removing cell types having unwanted cell markers. Other methods of stem cell purification or concentration can include the use of techniques such as counterflow centrifugal elutriation, equilibrium density centrifugation, velocity sedimentation at unit gravity, immune rosetting, immune adherence and T lymphocyte depletion.

Examples of stem cell markers that can be useful in these purification include, but are not limited to, FLK-1, AC133, CD34, c-kit, CXCR-4, Oct-4, Rex-1, CD9, CD13, CD29, CD44, CD166, CD90, CD105, SH-3, SH-4, TRA-1-60, TRA-1-81, SSEA-4, Sox-2, and the like. Examples of cell surface markers that can be used as markers of contaminating, unwanted cell types depends on the stem cell phenotype sought. For example, if collection of pluripotent hematopoietic cells is desired, contaminating cells will possess markers of commitment to the differentiated hematopoietic cells such as CD38 or CD33. If selection of stromal mesenchymal cells is desired, then contaminating cells would be detected by expression of hematopoietic markers such as CD45. Additionally, stem cells can be purified based on properties such as size, density, adherence to certain substrates, or ability to efflux certain dyes such as Hoechst 33342 or Rhodamine 123.

### EXAMPLES

The present compositions and methods will be understood more readily by reference to the following examples, which are provided by way of illustration and are not intended to be limiting in any way.

### Example 1

### Fabrication of a Liquid Crystal Cell Sorting Device with Tunable Wettability

A cell sorting device is manufactured from a polystyrene, plastic, or metal substrate. A rotatable carousel is formed with one or more apertures such that the one or more apertures are configured to receive glass platform microscope slides coated with octadecyltrichlorosilane (OTS). The one or more apertures are positioned throughout the periphery of the rotatable carousel such that the glass platforms are evenly spaced. In this regard, the apertures may be pre-formed with the polystyrene, plastic, or metal substrate or drilled into a carousel thereafter. Glass platforms are rinsed several times with ethanol to remove any uncured OTS monomer and subsequently dried. Approximately 1 μl of liquid crystal matrix selected from Table 2, as shown below, is dispensed onto each platform slide and any excess liquid crystal is removed with a syringe, thereby producing a planar interface.

Subsequently, 2-4 mg of Matrigel™ extracellular matrix (BD Biosciences, Franklin Lakes, N.J.), is resuspended in 8-20 ml of 0.1 M sodium bicarbonate buffer and added to the glass platform substrates containing the liquid crystal. The slides are then incubated at 37° C. for approximately 120 minutes to allow the apical film to form. The glass platforms, 75 mm×25 mm (diameter×height), are then reversibly affixed to the carousel by inserting the platforms containing the liquid crystal matrix into the apertures, thereby creating the rotatable carousel with liquid crystal matrix platform. In addition, a low voltage electric field source, such as an electrode, is electrically connected to the rotatable carousel.

An optoelectric polarized light microscope (BX60, Olympus, Tokyo, Japan) is arranged with respect to the one or more platforms, such that the microscope is configured to measure liquid crystal matrix orientation. The polarized light microscope is configured to observe optical orientation formed by light transmitted through liquid crystal matrices, such as those listed in Table 2. The images are obtained using a 20× objective lens with a 550 μm field of view between cross-polars. Images of the optical appearance of liquid crystals may also be captured with a digital camera (C-2020 Z, Olympus America Inc. (Melville, N.Y.)) that is attached to the polarized light microscope. A computer processor is also supplied for gathering and processing data generated from a cell sorting assay. The cell sorting device also includes a fluid flow chamber for cell removal following a cell sorting assay. Capture vessels are positioned with respect to the slides on the rotating carousel for collection of isolated cell populations.

TABLE 2
Liquid Crystal Matrices
Liquid Crystal Matrices

4-(3-acryloyloxypropyloxy)-benzoic acid 2-methyl-1,4-phenylene ester;
4-trans-propylcyclohexylcyanobenzene; 4-trans-butylcyclohexylcyano-
benzene; 4-trans-pentylcyclohexylcyanobenzene; 4-trans-heptylcyclohexyl-
cyanobenzene; 4-cyano-4′-trans-pentylcyclohexanebiphenyl; 4-trans-
propylcyclohexyl-4′-ethylbiphenyl; 4-trans-propylcyclohexyl-4′-
propylbiphenyl; 4-ethyl-4′-cyanobiphenyl; 4-propyl-4′-cyanobiphenyl;
4-butyl-4′-cyanobiphenyl; 4-pentyl-4′-cyanobiphenyl; and 4-heptyl-4′-
cyanobiphenyl.

The present disclosure is not to be limited in terms of the particular embodiments described in this application. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds compositions or biological systems, which can, of course, vary. It is also to be understood that the terminology used herein is for the purpose of describing particular embodiments only, and is not intended to be limiting.

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like include the number recited and refer to ranges which can be subsequently broken down into subranges as discussed above. Finally, as will be understood by one skilled in the art, a range includes each individual member. Thus, for example, a group having 1-3 proteins refers to groups having 1, 2, or 3 proteins. Similarly, a group having 1-5 proteins refers to groups having 1, 2, 3, 4, or 5 proteins, and so forth.

While various aspects and illustrative embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

All references cited herein are incorporated by reference herein in their entireties and for all purposes to the same extent as if each individual publication, patent, or patent application was specifically and individually incorporated by reference in its entirety for all purposes.

1. A method of cell sorting comprising:
depositing cells on a liquid crystal matrix;
measuring liquid crystal matrix orientation;
altering liquid crystal matrix wettability to induce a cellular response, wherein the cellular response produces a change in the liquid crystal matrix orientation;
detecting the change in the liquid crystal matrix orientation; and sorting the cells based on the change in the liquid crystal matrix orientation.

2. The method of claim 1, wherein the liquid crystal matrix includes an apical film selected from the group consisting of extracellular matrix, basement membrane extract, and EHS matrix.

3. (canceled)

4. The method of claim 1, further comprising removing the cells from the liquid crystal matrix, wherein the removing occurs after sorting the cells based on the change in the liquid matrix orientation.

5. The method of claim 4, wherein removing the cells from the liquid crystal matrix is by fluid flow or laser dissection.

6. (canceled)

7. The method of claim 1, wherein measuring the liquid crystal matrix orientation is by optoelectronic measuring.

8. (canceled)

9. The method of claim 1, wherein detecting the change in the liquid crystal matrix orientation is by optoelectronic detecting.

10. (canceled)

11. (canceled)

12. The method of claim 1, wherein the liquid crystal matrix is selected from the group consisting of: 4-(3-acryloyloxypropyloxy)-benzoic acid 2-methyl-1,4-phenylene ester; 4-trans-propylcyclohexylcyanobenzene; 4-trans-butylcyclohexylcyanobenzene; 4-trans-pentylcyclohexylcyanobenzene; 4-trans-heptylcyclohexylcyanobenzene; 4-cyano-4′-trans-pentylcyclohexanebiphenyl; 4-trans-propylcyclohexyl-4′-ethylbiphenyl; 4-trans-propylcyclohexyl-4′-propylbiphenyl; 4-ethyl-4′-cyanobiphenyl; 4-propyl-4′-cyanobiphenyl; 4-butyl-4′-cyanobiphenyl; 4-pentyl-4′-cyanobiphenyl; and 4-heptyl-4′-cyanobiphenyl.

13. The method of claim 1, further comprising applying ferroelectric nanoparticles to the liquid crystal matrix prior to altering the liquid crystal matrix wettability.

14. The method of claim 13, wherein the ferroelectric nanoparticles are selected from the group consisting of Sn₂P₂S₆, BaTiO₃, PbTiO₃, lead zirconate titanate (PZT), and combinations thereof.

15. The method of claim 1, wherein altering the liquid crystal matrix wettability occurs by applying a low voltage electric field of about 0.01 V/μm to about 0.1 V/μm.

16. (canceled)

17. (canceled)

18. (canceled)

19. (canceled)

20. A cell sorting apparatus comprising:
a rotatable carousel with one or more platforms, wherein the one or more platforms include a liquid crystal matrix configured to receive cells;
an electric source capable of providing a low voltage electric field to the one or more platforms; and
an optoelectronic device configured to detect one or more liquid crystal matrix orientations.

21. The apparatus of claim 20, further comprising a cell dispenser.

22. (canceled)

23. (canceled)

24. The apparatus of claim 20, wherein the liquid crystal matrix is selected from the group consisting of: 4-(3-acryloyloxypropyloxy)-benzoic acid 2-methyl-1,4-phenylene ester; 4-trans-propylcyclohexylcyanobenzene; 4-trans-butylcyclohexylcyanobenzene; 4-trans-pentylcyclohexylcyanobenzene; 4-trans-heptylcyclohexylcyanobenzene; 4-cyano-4′-trans-pentylcyclohexanebiphenyl; 4-trans-propylcyclohexyl-4′-ethylbiphenyl; 4-trans-propylcyclohexyl-4′-propylbiphenyl; 4-ethyl-4′-cyanobiphenyl; 4-propyl-4′-cyanobiphenyl; 4-butyl-4′-cyanobiphenyl; 4-pentyl-4′-cyanobiphenyl; and 4-heptyl-4′-cyanobiphenyl.

25. The apparatus of claim 20, wherein the liquid crystal matrix has an apical film selected from the group consisting of extracellular matrix, basement membrane extract, and EHS matrix.

26. The apparatus of claim 20, wherein the low voltage is selected to induce a change in wettability of the liquid crystal matrix.

27. (canceled)

28. (canceled)

29. The apparatus of claim 20, wherein the liquid crystal matrix further comprises ferroelectric nanoparticles selected from the group consisting of Sn₂P₂S₆, BaTiO₃, PbTiO₃, lead zirconate titanate (PZT), and combinations thereof.

30. The apparatus of claim 20, wherein the low voltage electric field is about 0.01 V/μm to about 0.1 V/μm.

31. (canceled)

32. (canceled)

33. A cell sorting method comprising:
depositing cells on one or more platforms containing a liquid crystal matrix, wherein the one or more platforms are affixed to a rotatable carousel;
rotating the carousel to align the one or more platforms with an electric field source;
applying an electric current to the one or more platforms, wherein the electric current induces a change in wettability of the liquid crystal matrix;
measuring the cells' response to the change in wettability, wherein the response depends on a cellular differentiation stage, and wherein the differentiation stage induces a measurable change in the matrix orientation; and
sorting the cells based on the response.

34. The method of claim 33, wherein rotating the carousel provides for separate, sequential or simultaneous alignment of the one or more platforms with the electric field source.

35. The method of claim 33, further comprising removing the cells from the liquid crystal matrix, wherein the removing occurs after sorting the cells based on the response.

36. (canceled)

37. (canceled)

38. The method of claim 33, wherein the liquid crystal matrix includes an apical film selected from the group consisting of matrigel or extracellular matrix.

39. (canceled)

40. The method of claim 33, wherein measuring the cells' response to the change in wettability is by optoelectronic measuring.

41. (canceled)

42. (canceled)

43. The method of claim 33, wherein the liquid crystal matrix is selected from the group consisting of: 4-(3-acryloyloxypropyloxy)-benzoic acid 2-methyl-1,4-phenylene ester; 4-trans-propylcyclohexylcyanobenzene; 4-trans-butylcyclohexylcyanobenzene; 4-trans-pentylcyclohexylcyanobenzene; 4-trans-heptylcyclohexylcyanobenzene; 4-cyano-4′-trans-pentylcyclohexanebiphenyl; 4-trans-propylcyclohexyl-4′-ethylbiphenyl; 4-trans-propylcyclohexyl-4′-propylbiphenyl; 4-ethyl-4′-cyanobiphenyl; 4-propyl-4′-cyanobiphenyl; 4-butyl-4′-cyanobiphenyl; 4-pentyl-4′-cyanobiphenyl; and 4-heptyl-4′-cyanobiphenyl.

44. The method of claim 33, further comprising applying ferroelectric nanoparticles to the liquid crystal matrix prior to applying the electric current.

45. The method of claim 44, wherein the ferroelectric nanoparticles are selected from the group consisting of Sn₂P₂S₆, BaTiO₃, PbTiO₃, lead zirconate titanate (PZT), and combinations thereof.

46. (canceled)

47. (canceled)

48. (canceled)

49. A method of manufacturing a cell sorting apparatus, the method comprising:
applying a liquid crystal matrix to one or more platforms, wherein the liquid crystal matrix is configured to receive cells;
introducing the one or more platforms to a rotatable carousel having one or more apertures such that the one or more apertures receive the one or more platforms;
electrically connecting a low voltage electric field source to the one or more platforms; and
arranging an optoelectronic device with respect to the one or more platforms, wherein the optoelectronic device is configured to measure liquid crystal matrix orientation.

50. The method of claim 49, wherein the liquid crystal matrix has an apical film selected from the group consisting of extracellular matrix, basement membrane extract, and EHS matrix.

51. (canceled)

52. The method of claim 49, wherein the liquid crystal matrix is selected from the group consisting of: 4-(3-acryloyloxypropyloxy)-benzoic acid 2-methyl-1,4-phenylene ester; 4-trans-propylcyclohexylcyanobenzene; 4-trans-butylcyclohexylcyanobenzene; 4-trans-pentylcyclohexylcyanobenzene; 4-trans-heptylcyclohexylcyanobenzene; 4-cyano-4′-trans-pentylcyclohexanebiphenyl; 4-trans-propylcyclohexyl-4′-ethylbiphenyl; 4-trans-propylcyclohexyl-4′-propylbiphenyl; 4-ethyl-4′-cyanobiphenyl; 4-propyl-4′-cyanobiphenyl; 4-butyl-4′-cyanobiphenyl; 4-pentyl-4′-cyanobiphenyl; and 4-heptyl-4′-cyanobiphenyl.

53. (canceled)
